(19) United States
(12) Patent Application Publication
(10) Pub. No.: US 2023/0037391 A1
(43) Pub. Date: Feb. 9, 2023

(54) COOLING BATH FOR MULTIPROCESSOR CIRCUIT BOARDS

(71) Applicant: Ivan KIRILLOV, Moscow (RU)

(72) Inventor: Ivan KIRILLOV, Moscow (RU)

(21) Appl. No.: 17/790,612

(22) PCT Filed: Jan. 23, 2020
(86) PCT No.: PCT/RU2020/000026

§ 371 Date: Jul. 1, 2022

(51) Int. Cl. H05K 7/20

(52) U.S. Cl. CPC H05K 7/20236; H05K 7/20272

(57) ABSTRACT

A system and a method are disclosed for a cooling bath designed to provide a sufficient and evenly distributed coolant flow throughout the bath. The cooling system includes a holding unit with a coolant distribution chamber that will distribute coolant through multiple distribution pipes beneath device chambers, promoting even distribution of coolant through the device chambers. An external pump causes coolant to be expelled from the cooling bath. The flow of coolant expelled from the cooling bath is controlled in a coolant separation chamber with a separation layer that bisects the coolant separation chamber. The separation layer is perforated with calibrated holes to slow down the speed of coolant exiting the cooling bath to prevent a funnel effect, protect the device chambers from coolant waves and coolant level fluctuation generated by the pump, and evenly distribute removal of hot coolant from the cooling bath.

### TECHNICAL FIELD

The disclosure generally relates to the field of cooling configurations for multiprocessor circuit boards.

### BACKGROUND

A circuit board holding unit, called a bath, holds a lot of circuit boards with processors that generates a lot of heat. To cool it down, dielectric fluid is propagated through heatsink ribs. But due to complicated flow patterns it is very difficult to design a proper bath construction that has enough flow and an equal distribution of flow through the heatsinks of the microprocessors, while also making it high in density (e.g., holding a large number of heat-generating circuit boards) and compact in size (e.g., 12 m×1.3 m×0.5 m).

For a conventional cooling baths, if the bath, i.e., a circuit board holding unit, is this large (12 meters (m) long with 4 rods of circuit boards) with a flow of 4,500 L per hour, it creates a number of problems. For example, difficulties reaching equal liquid flow distribution with lowest possible flow to remove heat from the heat exchanges of the chip mounts to the circuit boards (e.g., hash boards) are created. It also results in zero pressure because the bath is opened in the atmosphere. This is due to liquid losing pressure while flowing in the pipes and meeting barriers such heat exchangers. Yet another difficulty is minimization of flow that otherwise creates a very strong suction ability that causes a funnel at the liquid surface and sucks air.

### BRIEF DESCRIPTION OF DRAWINGS

The disclosed embodiments have other advantages and features which will be more readily apparent from the detailed description, the appended claims, and the accompanying figures (or drawings). A brief introduction of the figures is below.

Figure (FIG.) 1 illustrates one embodiment of a conventional cooling bath.

FIG. 2 illustrates a container for cooling baths according to one example embodiment.

FIG. 3 illustrates an exposed view of the container of FIG. 2 according to one example embodiment.

FIG. 4 illustrates a further exposed view of the container of FIG. 2 according to one example embodiment.

FIG. 5 illustrates an oil distribution flow outside of a container according to one example embodiment.

Figures (FIGS.) 6A-6C illustrate dimensions for a cooling bath according to one example embodiment.

FIG. 7 illustrates two coupled cooling baths according to one example embodiment.

FIG. 8 illustrates a cooling bath with circuit board installation chambers exposed according to one example embodiment.

FIG. 9 illustrates a cross-sectional view of a cooling bath with circuit board installation chambers exposed according to one example embodiment.

FIG. 10 illustrates components for a cooling bath according to one example embodiment.

FIG. 11 illustrates oil distribution piping for a cooling bath according to one example embodiment.

FIG. 12 illustrates circuit board and cable layouts within a cross section of a cooling bath according to one example embodiment.

FIG. 13 illustrates a schematic drawing of a top view of a cooling bath according to one example embodiment.

FIG. 14 illustrates a cross section view of an oil channel layout within a cooling bath according to one example embodiment.

FIG. 15 illustrates a transparent view of cooling bath 300a according to one example embodiment.

FIG. 16 illustrates a schematic drawing of a cross-sectional view of a cooling bath according to one example embodiment.

FIG. 17 illustrates a schematic drawing of a front view of a cooling bath according to one example embodiment.

FIG. 18 illustrates coolant flow inside a coolant distribution chamber of a cooling bath according to one example embodiment.

### DETAILED DESCRIPTION

The Figures and the following description relate to preferred embodiments by way of illustration only. It should be noted that from the following discussion, alternative embodiments of the structures and methods disclosed herein will be readily recognized as viable alternatives that may be employed without departing from the principles of what is listed in the appended claims.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

### Conventional Cooling Bath Structure

Figure (FIG.) 1 illustrates one embodiment of a conventional cooling bath. Present cooling bath designs are small-scale, liquid cooling baths that have small heat capacities (e.g., 200 kW maximum heat dissipation) compared to the heat capacity of the cooling bath layout described herein (e.g., 2,500 kW maximum heat dissipation).

### Configuration Overview

Disclosed is a cooling bath for multiprocessor circuit boards. The cooling bath is configured to dissipate large levels of heat generated from multiprocessor circuit boards. This large volume of heat is generated when the multiprocessor circuit boards are undertaking highly intensive computing (processing) activity, for example, bitcoin mining or complex, e.g., simulations (e.g., visual modeling).

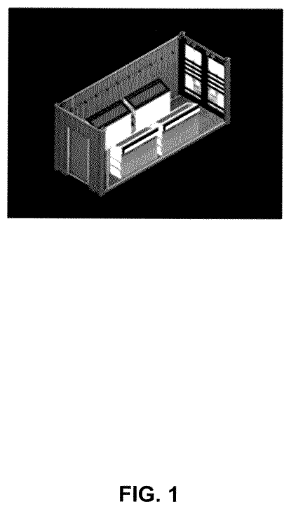

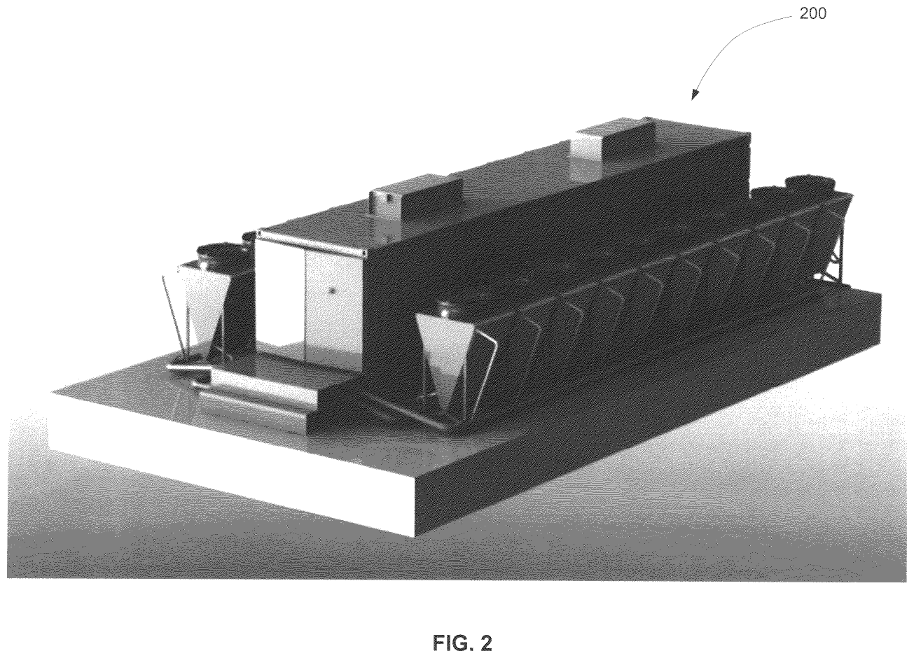

FIG. 2 illustrates container 200 for cooling baths. The term “cooling bath,” as referred to herein, describes any housing unit capable of cooling heat-generating electronic devices using a coolant to absorb heat from the heat-generating electronic devices. In some embodiments, container 200 is a 40-foot (ft) long (12.19 meters (m)) (or approximately 12 m) container such as an intermodal container. Each 40-ft container may dissipate over 2 MW of heat from installed circuit boards. Container 200 may hold multiple cooling baths. For example, a 12-meter container may hold two cooling baths, where each cooling bath is approximately 11 meters in length and 1 meter in width. Cooling bath dimensions are further described in the description of FIG. 6. In some embodiments, a container is approximately 6-meter (20-foot) long intermodal container that may hold a cooling bath that is half the length of the cooling bath contained by the 12.19-meter (40-foot) intermodal container. Such container in one embodiment may be approximately 1 meter in width. Cooling bath containers may be larger or smaller than container 200 because the structure of the cooling bath described herein allows for increased flexibility in sizing. These advantages are further described throughout the specification.

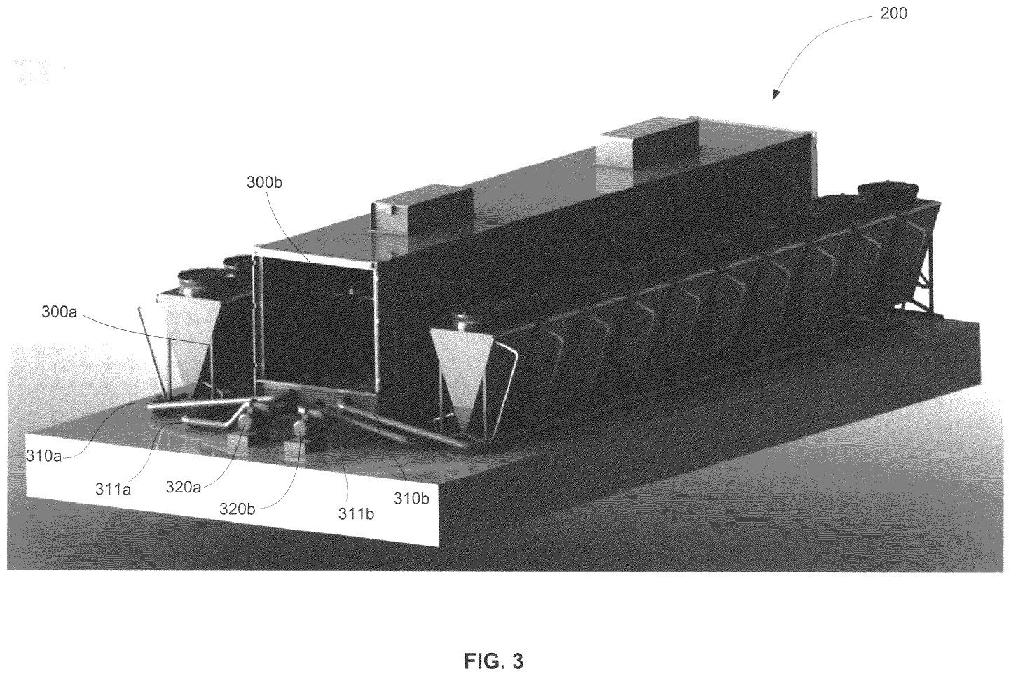

FIG. 3 illustrates an exposed view of container 200 of FIG. 2. Container 200 holds cooling baths 300a and 300b. A coolant may enter into container 200 through inlet pipes 310a and 310b, through cooling baths 300a and 300b, and exit cooling bath 300a, cooling bath 300b, and container 200 through outlet pipes 311a and 311b. The coolant may be a liquid with dielectric properties. To support a heat transfer process, a low viscosity and sufficient thermal conductivity are required of the coolant. For example, the coolant may have a viscosity of 5-15 centistokes (cST) at an operating temperature of 60 degrees Celsius and a thermal conductivity of at least 0.10 W (mK).

In some embodiments, the coolant is at an initial temperature as it enters through inlet pipes 310a and 310b. The coolant exits container 200 through outlet pipes 311a and 311b at a hotter temperature as it is heated by the circuit boards within the cooling bath that are dissipating heat. In some embodiments, the coolant is reused after exiting through outlet pipes 311a and 311b. Fans may be used to cool down the coolant and recirculate it through inlet pipes 310a and 310b. As shown in FIG. 2, fans align container 200 that cool the temperature of hot coolant exiting container 200. External pumps 320a and 320b may expel hot coolant through outlet pipes 311a and 311b.

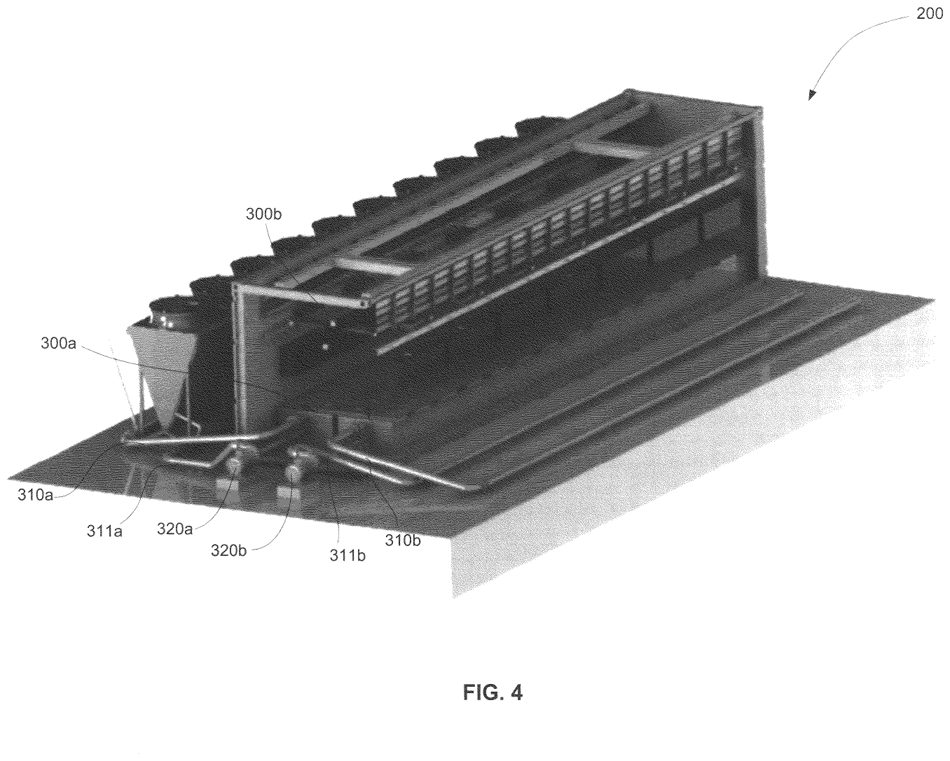

FIG. 4 illustrates a further exposed view of container 200 of FIG. 2. Cooling baths 300a and 300b are shown arranged side-by-side length-wise. The length of the cooling baths are substantially the length of the container to optimize space. The fans aligning the side of container 200 are removed from the view of FIG. 3 to show that inlet pipes 310a and 310b may not be the same pipe as outlet pipes 311a and 311b, respectively. Hot coolant may flow through pipes coupled to the fan assembly that do not have the same size as the inlet or outlet pipes coupled to the cooling baths.

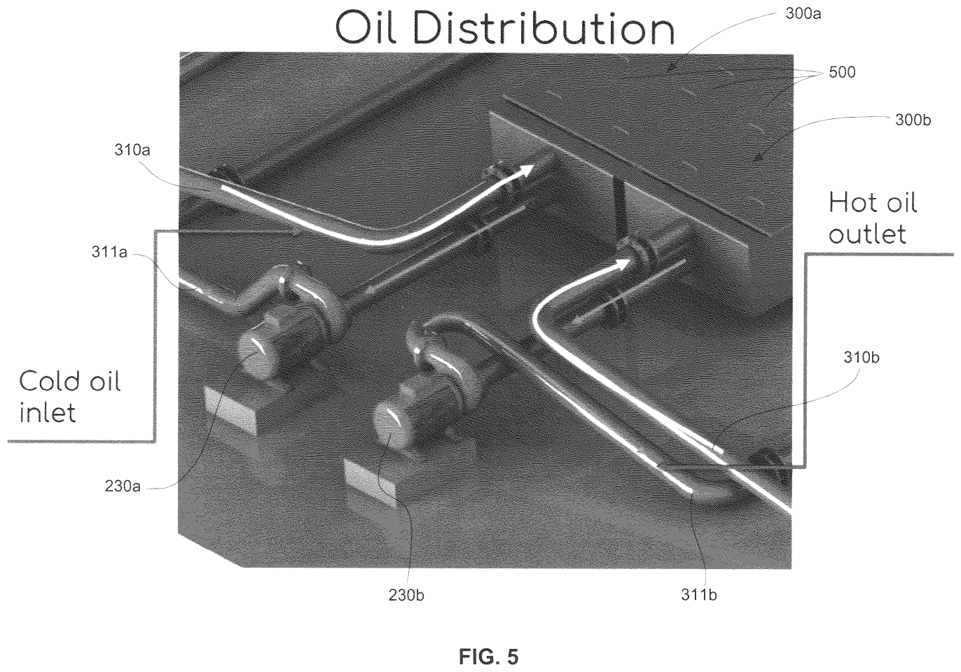

FIG. 5 illustrates an oil distribution flow outside of container 200. The flow of coolant that is at an initial temperature (e.g., a temperature cooler than the temperature of circuit boards) and is depicted with dotted arrows through inlet pipes 310a and 310b. The flow of coolant exiting container 200 is at a hotter temperature and is depicted with dashed arrows through outlet pipes 311a and 311b. External pumps 230a and 230b maintain the flow of coolant through cooling baths 300a and 300b, respectively. In some embodiments, coolant baths 300a and 300b are covered by lid 500. Lid 500 may be a uniform structure or may be comprised of two or more subsets of lids to cover the cooling bath. Lid 500 may be removable to access the circuit boards housed within the cooling bath. Although lid 500 of FIG. 5 is referenced using reference lines to only three subsets of lids to promote clarity in the drawing, lid 500 may include more than three subsets of lids in the lid structure over cooling bath 300a.

### Example Cooling Bath Structure

FIGS. 6A-6C illustrate example dimensions for a cooling bath. In one example configuration, the disclosed cooling bath may be structured from sheet metal. The cooling bath may have a main case and one or more pipe inlets and outlets. The main case may be constructed using a sheet metal bending machine that shapes the sheet metal into hollow rectangular shape. In one embodiment, all four sides may be bent and may be configured to weld along one length where two ends of the bent sheet metal meet. In one example configuration, the main case may be a length that meets the requirements for proper flow calculations, for example, 12 meters long. Given its length, in some example configurations the main case may be configured by welding multiple bent sheet metal “boxes” of less than total desired length in order to meet the desired length. The total length of the cooling bath is not limited but dependent on the necessary flow calculation. Thus, this solution is universal and can be expanded even to larger dimensions. FIG. 6A shows cooling baths 300a and 300b with lid 500 in a 3-dimensional (3D) view. FIGS. 6B and 6C illustrate example dimensions for a cooling bath in millimeters (mm) in a 2-dimensional (2D) view. FIG. 6B shows a front view of cooling bath 300a, where the dimensions of the front may be 984 mm in width, excluding the lid's dimensions, by 494 mm in height, including the lid's dimensions. The width of lid 500 that cover the width of cooling bath 300a may be 1064 mm.

The disclosed configuration may use an external pump to generate flow. In addition, the disclosed configuration also uses hot liquid movement as the liquid itself gets hotter when it moves from the bottom of the cooling bath to the top. This helps with self-circulation and lowers the demand on the external pump. In some embodiments, device chambers are located within cooling baths 300a and 300b, where each device chamber holds at least one module (e.g., integrated circuit chips) within the cavity of the chamber. Each module is placed on a base of the metal sheet with calibrated holes. In some embodiments, the metal sheet is composed of stainless steel or iron steel. For example, a coolant without water in it allows for an iron steel (i.e., not necessarily stainless) to be used because the absence of water prevents the iron steel sheet from rusting. The sheet over which the modules are placed, in some embodiments, is not necessarily metal. The liquid passes through those holes into the cavities and contacts the heatsinks of the circuit boards, thereby cooling the integrated circuit chips (or chips) through thermal transfer properties that transfer heat from the chips to the liquid via the sinks. Consequently, the hot liquid goes to the center of the bath, which is a suction section or a coolant separation chamber. The liquid level in this section is lower than in the section with modules and therefore the liquid may drop down to the separation chamber through holes located at the top of the walls of the device chambers. This design protects the device chambers with modules from the waves and level fluctuation generated by the pump suction and causes equally distributed removal of the hot liquid from the whole bath length.

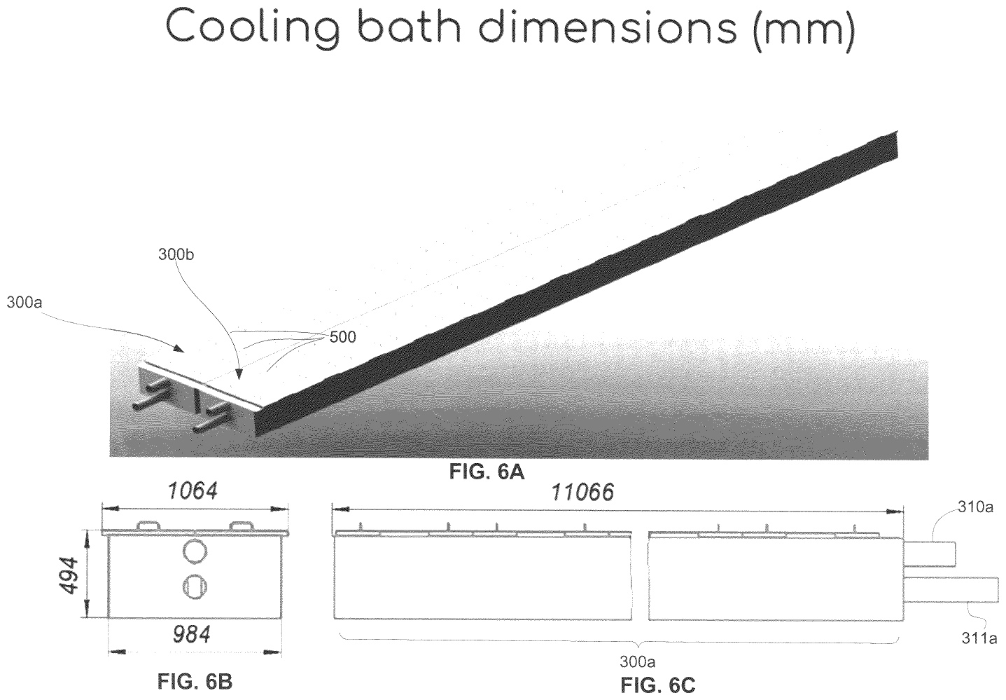

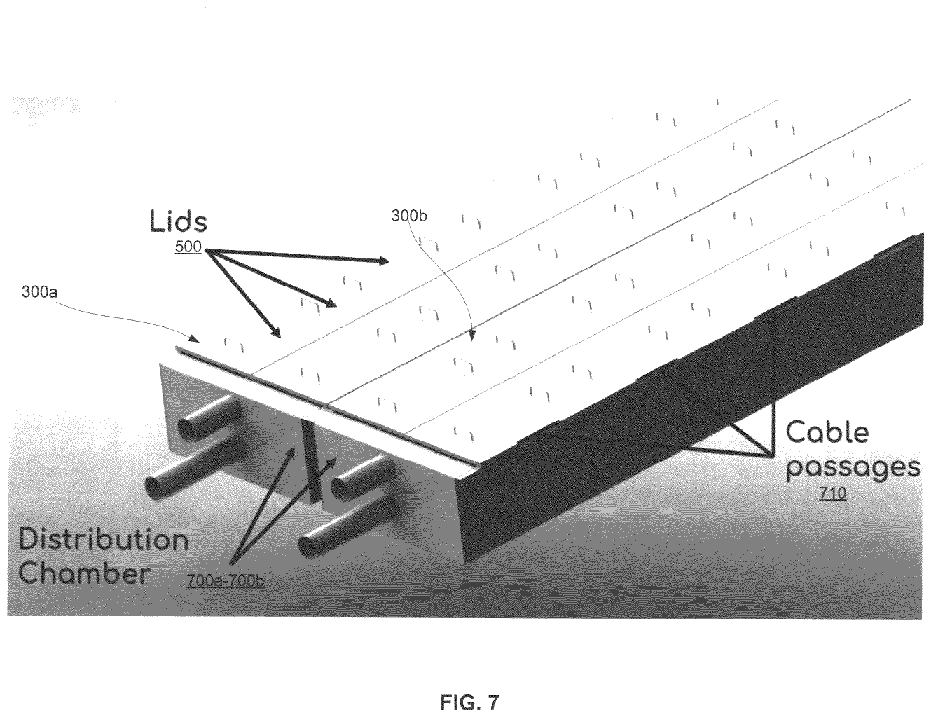

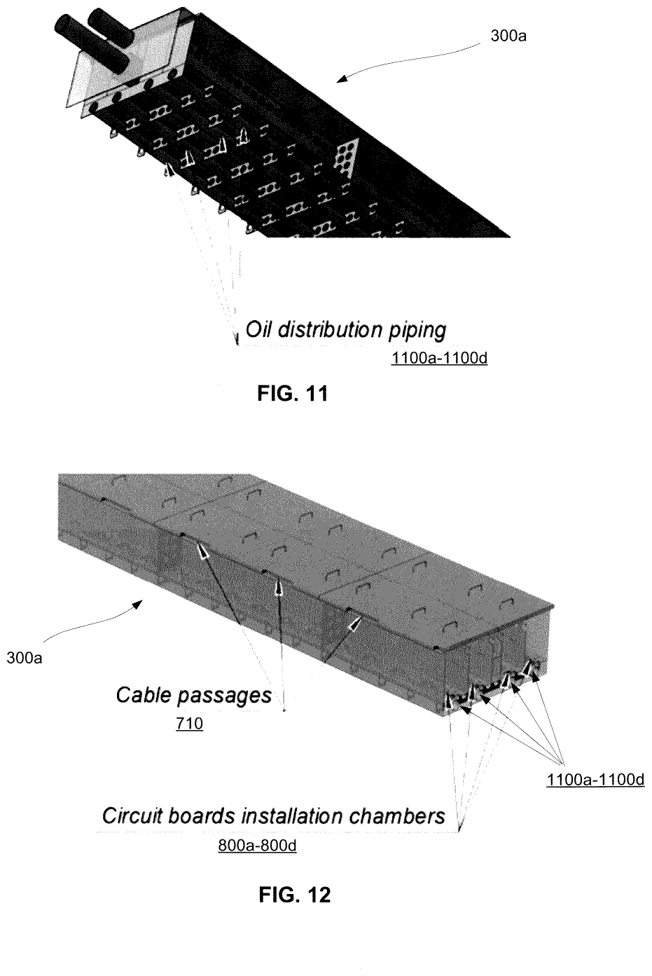

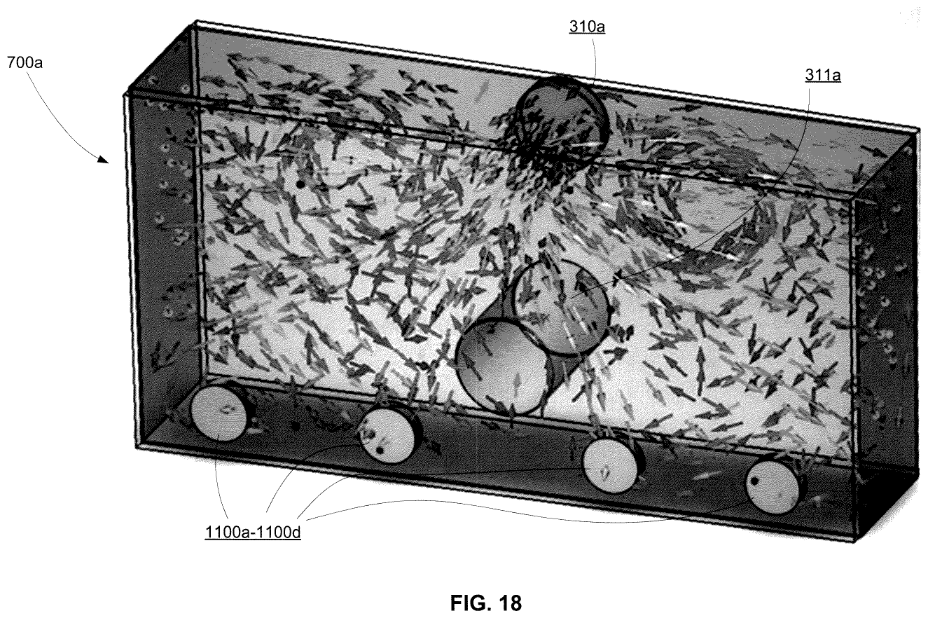

FIG. 7 illustrates two coupled cooling baths. Cooling bath 300a and 300b include coolant distribution chambers 700a and 700b, respectively. While only the coolant flow through cooling bath 300a will be described for ease of discussion, the flow through cooling bath 300b is similar. A liquid goes inside cooling bath 300a through an inlet pipe to coolant distribution chamber 700a. This chamber is designed to split the flow into several parts with high precision. The chamber may be designed using a computer simulation of the liquid flow (e.g., as shown in FIG. 18). For example, the flow may be divided into four equal parts and passes through four pipes of smaller diameter for the entire length of the bath. The smaller pipes may be referred to as distribution pipes. In some embodiments, the lengths of the smaller pipes are substantially the same as the length of the cooling bath. For example, the lengths of the smaller pipes are shorter than length of the cooling bath such that the smaller pipes fit inside the cooling bath (e.g., at most 5% less than the length of the cooling bath). The smaller pipes, although not shown in FIG. 7, are depicted in, for example, FIG. 11. The number of small pipes may increase or decrease depending on the size of the cooling bath. For example, four small pipes are housed within a cooling bath having a width of approximately 1 meter and eight small pipes are housed within a cooling bath having a width of approximately 2 meters. In some embodiments, each pipe of the small pipes may include calibrated holes. In such embodiments the size of the holes may be based on the total flow within the cooling bath, the length of the cooling bath, or a combination thereof. The calibrated holes may be located at the bottom of the smaller pipes to enforce equal distribution of the coolant throughout the cooling bath. The coolant exits the smaller pipes from the holes at the bottom of the smaller pipes, mixes in the bottom of the cooling bath, and rises upwards in the cooling bath at a constant speed.

In some embodiments, the cooling baths 300a and 300b may include a roof, e.g., lid 500. Cable passages 710 may be included in the lid 500, which may allow cables to be passed through lid 500 to the devices within cooling baths 300a and 300b. All lids or a subset of lids may be structured to have a cable passage. For example, lids on either side of the coupled cooling baths may have cable passages 710 while the remaining lids do not.

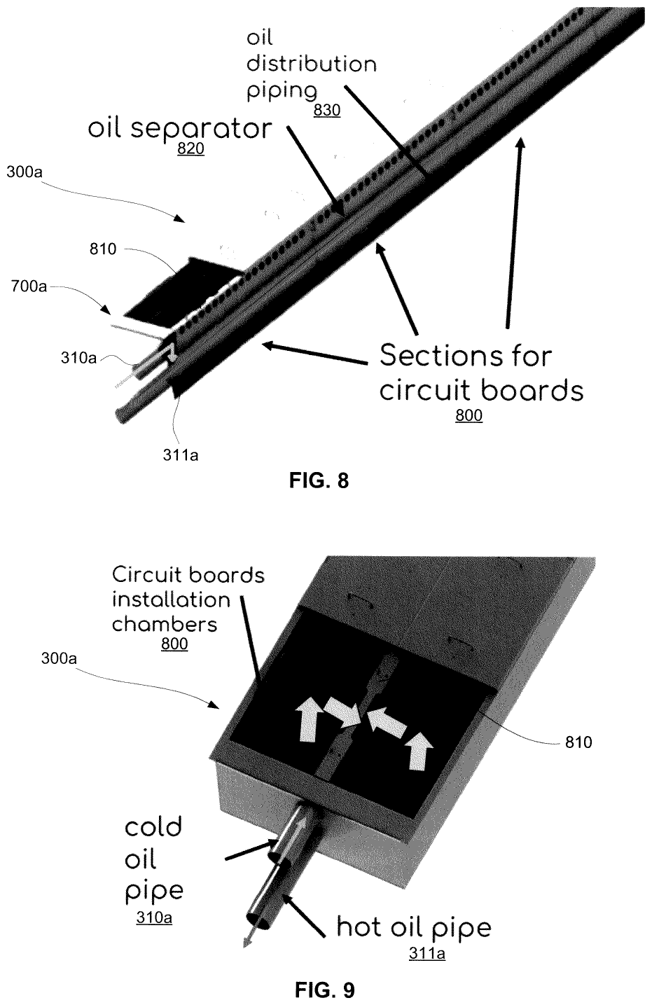

FIG. 8 illustrates cooling bath 300a with circuit board installation chambers 800 exposed. Dotted arrows depict a flow of coolant into cooling bath 300a through inlet pipe 310a. Coolant enters cooling bath 300a through inlet pipe 310a into coolant distribution chamber 700a. Coolant propagates into smaller pipes that are located at the bottom of cooling bath 300a. Coolant exits the smaller pipes or oil distribution piping 830 through calibrated holes in oil distribution piping 830 and fill cooling bath 300a, including device chambers or sections 800. In some embodiments, each device chamber of device chambers 800 includes a cavity to hold a device (e.g., a circuit board). Device chambers 800 may be separated from oil distribution piping 830 by a metal sheet with calibrated holes. The holes are calibrated for equal distribution of the coolant through device chambers 800. Coolant enters and begins to fill device chambers 800, contacting the heatsinks of circuit boards within device chambers 800, before entering a suction section between chambers. The suction section or coolant separation chamber is described further in the description of FIG. 9. The flow of coolant expelled from the coolant separation chamber in FIG. 8 is depicted through dashed arrows pointing out of outlet pipe 311a.

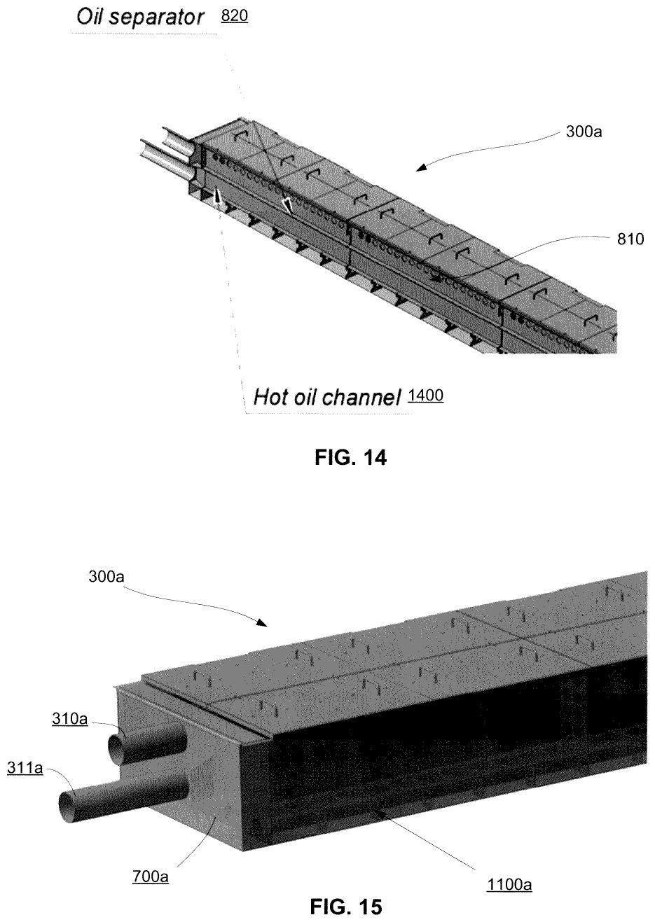

FIG. 9 illustrates a cross-sectional view of cooling bath 300a with device chambers 800 exposed. Dotted arrows depict the flow of coolant into cooling bath 300a through inlet pipe or cold oil pipe 310a. Although labeled as “cold oil pipe,” the coolant is not necessarily oil-based. Similar, for outlet pipe or hot oil pipe 311a, the coolant expelled from cooling bath 300a is not necessarily oil-based. In some embodiments, the coolant fills device chambers 800 and absorbs the heat from the circuit boards in chambers 800. The flow of coolant through chambers 800 and into coolant separation chamber 810 is depicted through dotted arrows. The coolant rises upwards and fills chambers 800. The coolant is propagated towards the center of cooling bath 300a to coolant separation chamber 810. Once inside coolant separation chamber 810, the coolant is, in some embodiments, propagated through a separation layer that bisects coolant separation chamber 810. The separation layer may be a metal sheet with calibrated holes structured to slow the flow of coolant being expelled from cooling bath 300a. The separation layer is further described in the description of FIG. 14. Without the separation layer, the flow of coolant exiting cooling bath 300a may be very large, creating a funnel effect with the coolant. This funnel causes air to be expelled from cooling bath 300a in addition to coolant. The separation layer contributes an effect similar to a negative pressure within a portion of chamber 810 (e.g., the bottom portion of chamber 810) that prevents air from entering the portion and being expelled with the coolant. Controlling the speed of the coolant in different portions of chamber 810 may prevent the funnel effect. For example, the separation layer splits chamber 810 into top and bottom portions, where the coolant is expelled from the bottom portion through outlet pipe 311a. Coolant travels from the top portion to the bottom portion through calibrated holes in the separation layer. These calibrated holes slow the flow of coolant from the top portion into the bottom portion, causing the coolant to flow slower in the top portion than in the bottom portion. By slowing the flow of coolant that is being expelled by an external pump (e.g., external pump 320a), chamber 810 may be constantly filled with coolant and a funnel effect is prevented.

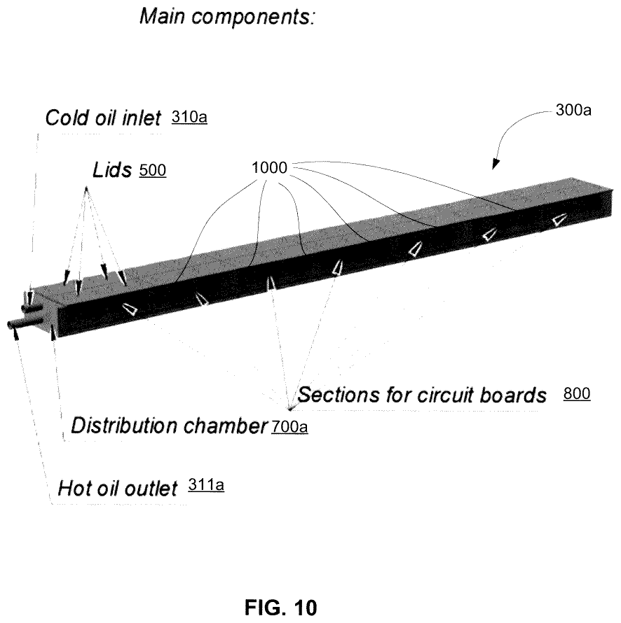

FIG. 10 illustrates components for cooling bath 300a. Cooling bath 300a includes one or more chambers 800 for devices (e.g., circuit boards), one or more corresponding lid 500, and coolant distribution chamber 700a. Device chambers 800 may be separated by walls 1000 that are perforated with calibrated holes. Cooling bath 300a may include or be operatively engaged with inlet pipe 310a and outlet pipe 311a. In some embodiments, inlet pipe 310a may be for cold oil and outlet pipe 311a may be for hot oil.

FIG. 11 illustrates oil distribution piping for a cooling bath. In some embodiments, coolant enters cooling bath 300a at the coolant distribution chamber and flows through distribution pipes 1100a-1100d. In some embodiments, distribution pipes 1100a-1100d are smaller than the inlet pipe (e.g., pipe 310a). Each of these smaller pipes may include calibrated holes along the length of the pipe. In some embodiments, the calibrated holes are located at the bottom of distribution pipes 1100a-1100d (i.e., the side closest to the floor of cooling bath 300a) to promote even distribution of coolant flow. Distribution pipes 1100a-1100d are closed at one end (e.g., closed ends of the distribution pipes) such that coolant exits through the calibrated holes at the bottom of the pipes. Coolant may fill the bottom of cooling bath 300a and evenly rise through device chambers (e.g., chambers 800). The size of these holes may be calculated for a particular bath based on the total flow and length of the bath. In addition, a width of the bath may be increased with a larger number of pipes. Each pipe may be located under each row of a circuit board module. Hence, each module will get equal flow of the liquid going from the pipe in the bottom to the top.

FIG. 12 illustrates circuit board and cable layouts within a cross section of cooling bath 300a. In the cross section of cooling bath 300a are four device chambers 800a-800d. Device chambers 800a-800d are located above distribution pipes 1100a-1100d, respectively. The floor of device chambers 800a-800d may be a metal sheet with calibrated holes to control the flow of coolant entering chambers 800 through distribution pipes 1100a-1100d. Chambers 800 may be covered with a respective lid, and within each lid may be a cable passage of cable passages 710.

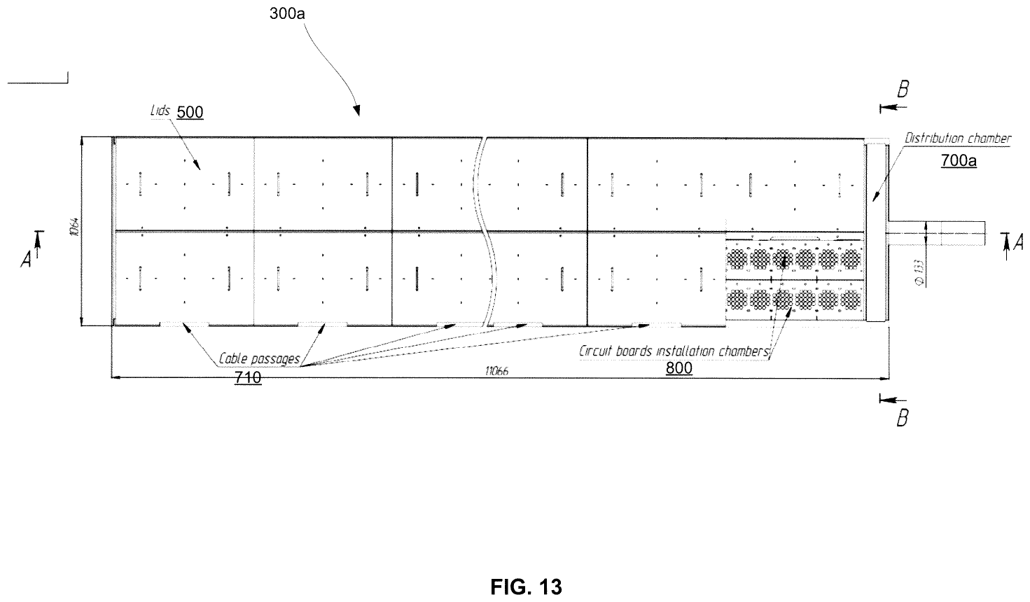

FIG. 13 illustrates a schematic drawing of a top view of cooling bath 300a. The dimensions of the top of cooling bath 300a are shown to be 1064 mm in width and 11066 mm in length. In some embodiments, both inlet and outlet pipes are 133 mm in diameter. Coolant enters coolant distribution chamber 700a to be distributed through multiple pipes along the bottom of cooling bath 300a (e.g., distribution pipes 1100a-1100d). Distribution pipes 1100a-1100d may be approximately the length of cooling bath 300a or within a predetermined distance from the length of cooling bath 300a (e.g., 1054 mm ±5 mm). The floor of device chambers 800 include calibrated holes to allow for coolant to propagate from the distribution pipes underneath. Lid 500 covering device chambers 800 include cable passages 710. In some embodiments, not all lids include cable passages (e.g., only lids on one side of cooling bath 300a include cable passages 710).

FIG. 14 illustrates a cross section view of an oil channel layout within cooling bath 300a. Specifically, the cross section intersects cooling bath 300a length-wise at the center of the oil separation chamber (e.g., chamber 810). Oil separator or separator layer 820 bisects chamber 810 into a top portion and a bottom portion, where the bottom portion is hot oil channel 1400. Although the term “oil” is used in FIG. 14 to refer to the coolant, the coolant is not necessarily oil-based. Hot coolant flows from device chambers 800 into chamber 810 through calibrated holes in the walls of chambers 800. In some embodiments, these calibrated holes are located towards the tops of the walls of chambers 800. Oil separation chamber 810 may share at least one wall with device chambers 800 such that the walls of chamber 810 includes calibrated holes to allow for coolant to flow into chamber 810 (e.g., from calibrated holes at the top, filling chamber 810 from the bottom). Separator layer 820 inside chamber 810 may be a metal sheet with calibrated holes to slow the flow of hot coolant expelled from chamber 810 and prevent a funnel effect.

FIG. 15 illustrates a transparent view of cooling bath 300a. The walls of coolant distribution chamber 700a are transparent to show that inlet pipe 310a leads to coolant distribution chamber 700a while outlet pipe 311a penetrates through coolant distribution chamber 700a to expel hot coolant out of cooling bath 300a. The openings of distribution pipes 1100 (e.g., open ends of the distribution pipes) are shown towards the bottom of coolant distribution chamber 700a. While only distribution pipe 1100a is shown in FIG. 15, distribution pipes 1100b-1100d are structured parallel to pipe 1100a at the bottom of cooling bath 300a. A device chamber (e.g., chamber 800a) is shown above distribution pipe 1100a. The device chambers may be separated by a wall (e.g., wall 1000) with calibrated holes to evenly distribute coolant through chambers 800.

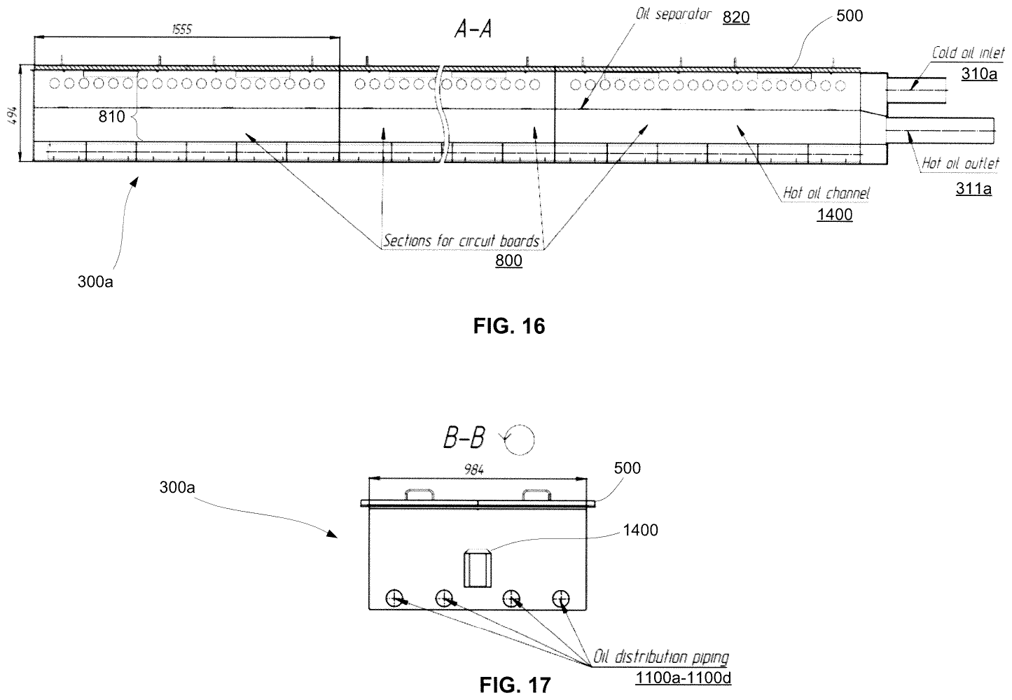

FIG. 16 illustrates a schematic drawing of a cross-sectional view of cooling bath 300a. The height of the cross-section of cooling bath 300a, including the height of lid 500, is 494 mm. The length of a device chamber of chambers 800 is 1555 mm. Coolant separation chamber 810 is shown above distribution pipes and bisected by separator layer 820. Hot oil channel 1400 is coupled to outlet pipe 311a through, and not open to, the coolant distribution chamber where cold coolant is entering cooling bath 300a through inlet pipe 310a.

FIG. 17 illustrates a schematic drawing of a front view of cooling bath 300a. The width of the front of cooling bath 300a is shown to be 984 mm, excluding the edges of lid 500. Hot oil channel 1400 is above distribution pipes 1100a-1100d and located towards the center of cooling bath 300a.

FIG. 18 illustrates coolant flow inside coolant distribution chamber 700a of cooling bath 300a. Arrows depicted within distribution chamber 700a shows the direction and velocity of coolant flow, where the darkest arrows (i.e., the arrows with the most dots or stippling) represent a high velocity. Velocity lowers as the depicted arrows transition from most stippling to least stippling. Coolant enters coolant distribution chamber 700a through inlet pipe 310a. Coolant circulates within chamber 700a around outlet pipe 311a, which penetrates through chamber 700a. Coolant exits chamber 700a through the openings of distribution pipes 1100a-1100d (e.g., open ends of the distribution pipes).

### Mathematical Foundation for Liquid Flow Distribution Calculation

Liquid flow distribution in the bath may be calculated using a combination of Navier-Stokes equations and validated using computer simulation.

Mass may be analyzed using Equation 1.

$$\frac{d ρ}{dt} + \frac{d}{{dx}_{k}} ( ρ * {U}_{k} ) = 0 \qquad Equation 1$$

Momentum may be analyzed using Equation 2.

$$\frac{d ( ρ \cdot {U}_{i} )}{dt} + \frac{d}{{dx}_{k}} ( {ρ}_{{U}_{i}} \cdot {U}_{i} - {τ}_{ik} ) + \frac{dP}{{dx}_{i}} = {S}_{i} \qquad Equation 2$$

Energy may be analyzed using Equation 3.

$$\frac{d ( ρ \cdot E )}{dt} + \frac{d}{{dx}_{k}} ( ( ρ \cdot E + P ) \cdot {U}_{k} + {q}_{k} - {τ}_{ik} \cdot {U}_{i} ) = {S}_{k} {U}_{k} + {Q}_{H} \qquad Equation 3$$

where, for Equations 1-3, t is time, U is medium velocity, P is pressure, ρ is density, Sᵢ is external body forces per unit mass of current fluid, Sᵢ=S_{i porous}+S_{i gravity}+S_{i rotation}, S_{i porous} is the resistance of porous fluid, S_{i gravity} is the gravity effect, S_{i rotation} is the effect of coordinate system rotation, E is the total energy of current fluid unit mass, Q_{H} is the heat generated by a heat source per fluid unit volume, τ_{i k} is the viscous-shear stress tensor, and qᵢ is the diffusion heat flux.

Equation 4 may be used to analyze Newtonian fluid viscous-shear stress tensors.

$${τ}_{ij} = μ \cdot ( \frac{{dU}_{i}}{{dx}_{j}} + \frac{{dU}_{j}}{{dx}_{i}} - \frac{2}{3} \frac{{dU}_{i}}{{dx}_{j}} \cdot {δ}_{ij} ) - \frac{2}{3} \cdot ρ \cdot K \cdot {δ}_{ij} \qquad Equation 4$$

where μ=μᵢ+μₜ, μᵢ is the dynamic viscosity factor, μₜ is the turbulent viscosity factor, δᵢⱼ is the Kronecker delta-function (δᵢⱼ=1 when i=j, δᵢⱼ=0 when i≠j), and K is the kinetic energy of turbulence.

Equations 5 and 6 may be used in the turbulence model in equations 7 and 8.

$${μ}_{t} = {f}_{μ} \cdot \frac{{C}_{μ} \cdot ρ \cdot {K}^{2}}{ε} \qquad Equation 5$$

$$f μ = [ 1 - exp ( - 0.025 {R}_{y} ) ] 2 \cdot ( 1 + \frac{20.5}{{R}_{j}} ) \qquad Equation 6$$

where

$$Ry = \frac{ρ \cdot y \cdot \sqrt{K}}{{μ}_{i}} , {R}_{j} = \frac{ρ \cdot {K}^{2}}{{μ}_{i} ε} ,$$

y is the distance from a wall surface, and c is the dissipation of the turbulence kinetic energy.

$$\frac{d ( ρ \cdot K )}{dt} + \frac{d}{{dx}_{k}} ( ρ \cdot {U}_{k} \cdot K ) = \frac{d}{{dx}_{i}} ( ( {μ}_{i} + \frac{{μ}_{t}}{{δ}_{K}} ) \cdot \frac{dK}{{dx}_{k}} + {S}_{k} \qquad Equation 7$$

$$\frac{d ( ρ \cdot ε )}{dt} + \frac{d}{{dx}_{k}} ( ρ \cdot {U}_{k} \cdot ε ) = \frac{d}{{dx}_{i}} ( ( {μ}_{i} + \frac{{μ}_{t}}{{δ}_{ε}} ) \cdot \frac{d ε}{{dx}_{k}} + {S}_{ε} \qquad Equation 8$$

### Where:

$${S}_{K} = {τ}_{ij}^{R} \frac{{dU}_{i}}{{dx}_{j}} - ρ \cdot ε + {μ}_{i} \cdot {P}_{B}$$

$${S}_{ε} = {C}_{ε 1} \cdot \frac{ε}{K} ( {f}_{1} \cdot {τ}_{ij}^{R} \frac{{dU}_{i}}{{dx}_{j}} + {μ}_{i} \cdot {C}_{B} \cdot {P}_{B} ) - {C}_{ε 2} \cdot {f}_{2} \cdot \frac{ρ \cdot {ε}^{2}}{K}$$

$${τ}_{ij}^{R} = {μ}_{i} \cdot ( \frac{{dU}_{i}}{{dx}_{j}} + \frac{{dU}_{j}}{{dx}_{i}} - \frac{2}{3} \frac{{dU}_{i}}{{dx}_{j}} \cdot {δ}_{ij} ) - \frac{2}{3} \cdot ρ \cdot K \cdot {δ}_{ij}$$

$${P}_{B} = - \frac{{ℊ}_{i} \cdot \frac{1}{ρ}}{{δ}_{B}} \cdot \frac{dP}{{dx}_{i}}$$

$${f}_{1} = 1 + {( \frac{0.05}{{f}_{μ}} )}^{3}$$

$${f}_{2} = 1 - exp ( - {R}_{j}^{2} )$$

and where gᵢ is the gravitational component in coordinate x, δ_{B}=0.9, C_{ε1}=1.44, C_{ε2}=1.92, δ_{ε}=1.3, and δ_{K}=1. Additionally, C_{B}=1 when P_{B}>0 and C_{B}=0 when P_{B}≤0.

Diffusion heat flux may be calculated using Equation 9.

$${q}_{k} = - ( \frac{{μ}_{j}}{Pr} + \frac{{μ}_{i}}{{δ}_{c}} ) {C}_{P} \cdot \frac{dT}{{dx}_{k}} \qquad Equation 9$$

where k=1, 2, 3, δ_{C}=0.9, Pr is the Prandtl number, Cₚ is the specific heat at a constant P, and T is the absolute temperature. At laminar flow, μᵢ=0 and K=0. f_{μ} is the transition function from laminar flow to turbulent and vice versa using wall functions.

### Additional Configuration Considerations

An advantage of the cooling bath layout described herein is that the structure has the ability to scale to many different bath sizes with varying quantities of installed devices (e.g., circuit board modules), while keeping the cooling efficiency constant and equal at any particular point in the bath. The construction of the coolant distribution chamber and the number of oil distribution pipes may be mathematically recalculated depending on the target flow and requested bath dimensions. The cooling bath layout described herein is an improvement upon conventional bath layouts that are complex and are low in density (e.g., a low number of circuit boards installed in a limited space). Existing solutions generate higher coolant flow with lower liquid temperatures in order to remove enough heat from the installed circuit boards. The equal flow distribution in the cooling bath structure described herein allows for a higher density of circuit boards to be installed while maintaining heat transfer with lower flow. Thus, the cooling bath provides equal cooling for all circuit boards, a vital function for stable operation of the circuit boards. The higher density of circuit boards capable of being installed in the cooling bath also reduces the cost of cooling per circuit board (e.g., less cooling baths are needed for to cool a given number of circuit boards). As compared to conventional baths that need lower coolant temperatures, the cooling bath is also less sensitive to external cooling systems because higher-temperature coolant may be used to remove heat from the installed circuit boards.

This design is not restricted by the size and quantity of the circuit board modules. For any existing and future designed circuit board installations that require effective removing of the generated heat while under load, this design can easily be mathematically recalculated and mechanically modified. This means that this solution is universal, reaching maximum density and cooling efficiency with any desired dimension and circuit board specification.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Certain embodiments are described herein as including logic or a number of components, modules, or mechanisms. Modules may constitute either software modules (e.g., code embodied on a machine-readable medium or in a transmission signal) or hardware modules. A hardware module is tangible unit capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as a hardware module that operates to perform certain operations as described herein.

In various embodiments, a hardware module may be implemented mechanically or electronically. For example, a hardware module may comprise dedicated circuitry or logic that is permanently configured (e.g., as a special-purpose processor, such as a field programmable gate array (FPGA) or an application-specific integrated circuit (ASIC)) to perform certain operations. A hardware module may also comprise programmable logic or circuitry (e.g., as encompassed within a general-purpose processor or other programmable processor) that is temporarily configured by software to perform certain operations. It will be appreciated that the decision to implement a hardware module mechanically, in dedicated and permanently configured circuitry, or in temporarily configured circuitry (e.g., configured by software) may be driven by cost and time considerations.

Accordingly, the term “hardware module” should be understood to encompass a tangible entity, be that an entity that is physically constructed, permanently configured (e.g., hardwired), or temporarily configured (e.g., programmed) to operate in a certain manner or to perform certain operations described herein. As used herein, “hardware-implemented module” refers to a hardware module. Considering embodiments in which hardware modules are temporarily configured (e.g., programmed), each of the hardware modules need not be configured or instantiated at any one instance in time. For example, where the hardware modules comprise a general-purpose processor configured using software, the general-purpose processor may be configured as respective different hardware modules at different times. Software may accordingly configure a processor, for example, to constitute a particular hardware module at one instance of time and to constitute a different hardware module at a different instance of time.

Hardware modules can provide information to, and receive information from, other hardware modules. Accordingly, the described hardware modules may be regarded as being communicatively coupled. Where multiple of such hardware modules exist contemporaneously, communications may be achieved through signal transmission (e.g., over appropriate circuits and buses) that connect the hardware modules. In embodiments in which multiple hardware modules are configured or instantiated at different times, communications between such hardware modules may be achieved, for example, through the storage and retrieval of information in memory structures to which the multiple hardware modules have access. For example, one hardware module may perform an operation and store the output of that operation in a memory device to which it is communicatively coupled. A further hardware module may then, at a later time, access the memory device to retrieve and process the stored output. Hardware modules may also initiate communications with input or output devices, and can operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Similarly, the methods described herein may be at least partially processor-implemented. For example, at least some of the operations of a method may be performed by one or processors or processor-implemented hardware modules. The performance of certain of the Operations may be distributed among the one or more processors, not only residing within a single machine, but deployed across a number of machines. In some example embodiments, the processor or processors may be located in a single location (e.g., within a home environment, an office environment or as a server farm), while in other embodiments the processors may be distributed across a number of locations.

The one or more processors may also operate to support performance of the relevant operations in a “cloud computing” environment or as a “software as a service” (SaaS). For example, at least some of the operations may be performed by a group of computers (as examples of machines including processors), these operations being accessible via a network (e.g., the Internet) and via one or more appropriate interfaces (e.g., application program interfaces (APIs).)

The performance of certain of the operations may be distributed among the one or more processors, not only residing within a single machine, but deployed across a number of machines. In some example embodiments, the one or more processors or processor-implemented modules may be located in a single geographic location (e.g., within a home environment, an office environment, or a server farm). In other example embodiments, the one or more processors or processor-implemented modules may be distributed across a number of geographic locations.

Some portions of this specification are presented in terms of algorithms or symbolic representations of operations on data stored as bits or binary digital signals within a machine memory (e.g., a computer memory). These algorithms or symbolic representations are examples of techniques used by those of ordinary skill in the data processing arts to convey the substance of their work to others skilled in the art. As used herein, an “algorithm” is a self-consistent sequence of operations or similar processing leading to a desired result. In this context, algorithms and operations involve physical manipulation of physical quantities. Typically, but not necessarily, such quantities may take the form of electrical, magnetic, or optical signals capable of being stored, accessed, transferred, combined, compared, or otherwise manipulated by a machine. It is convenient at times, principally for reasons of common usage, to refer to such signals using words such as “data,” “content,” “bits,” “values,” “elements,” “symbols,” “characters,” “terms,” “numbers,” “numerals,” or the like. These words, however, are merely convenient labels and are to be associated with appropriate physical quantities.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

Some embodiments may be described using the expression “coupled” and “connected” along with their derivatives. It should be understood that these terms are not intended as synonyms for each other. For example, some embodiments may be described using the term “connected” to indicate that two or more elements are in direct physical or electrical contact with each other. In another example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the invention. This description should be read to include one or at least one and the singular also includes the plural unless it is obvious that it is meant otherwise.

While particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the method and apparatus disclosed herein without departing from the spirit and scope defined in the appended claims.

1. A cooling system comprising:
an inlet pipe;
a holding unit comprising:
a coolant distribution chamber coupled with the inlet pipe;
a plurality of distribution pipes coupled with the coolant distribution chamber,
a respective distribution pipe comprising:
a first plurality of calibrated holes along a length of the respective distribution pipe,
an open end structured to receive coolant from the coolant distribution chamber, and
a closed end that is opposite to the open end and structured to prevent the coolant from flowing through the closed end;
a plurality of device chambers, a respective device chamber comprising:
a cavity structured to contain a device that generates heat,
a first side comprising a second plurality of calibrated holes structured to allow the coolant to flow from the first plurality of calibrated holes to the cavity, and
a second side comprising a third plurality of calibrated holes structured to allow the coolant to flow out of the respective device chamber; and
a coolant separation chamber coupled to at least one device chamber of the plurality of device chambers, the coolant separation chamber comprising:
a separator layer bisecting the coolant separation chamber into a first portion of the coolant separation chamber and a second portion of the coolant separation chamber, and
a fourth plurality of calibrated holes in the separator layer, the fourth plurality of calibrated holes structured to allow coolant to flow from the first portion of the coolant separation chamber into the second portion of the coolant separation chamber;
an outlet pipe coupled with the coolant separation chamber; and
an external pump coupled with the outlet pipe to expel the coolant from the coolant separation chamber through the outlet pipe.

2. The cooling system of claim 1, wherein the coolant is a liquid with a dielectric property of at least 0.10 watts (W).

3. The cooling system of claim 1, wherein the device is a circuit board.

4. The cooling system of claim 1, wherein the length of each pipe of the plurality of distribution pipes is substantially similar to a length of the holding unit.

5. The cooling system of claim 1, wherein the coolant separation chamber is coupled to the at least one device chamber such that the coolant flows from the at least one device chamber through respective third pluralities of calibrated holes into the coolant separation chamber.

6. The cooling system of claim 5, wherein the respective third pluralities of calibrated holes are sized based on at least one of the total coolant within the holding unit and a length of the holding unit.

7. The cooling system of claim 1, wherein the plurality of distribution pipes are located beneath the coolant separation chamber.

8. The cooling system of claim 1, wherein the outlet pipe is coupled with the second portion of the coolant separation chamber.

9. The cooling system of claim 1, wherein a first device chamber of the plurality of device chambers and a second device chamber of the plurality of device chambers are arranged contiguously above a pipe of the plurality of distribution pipes.

10. The cooling system of claim 1, wherein the separator layer is a metal sheet.

11. A method for cooling a holding unit, the method comprising:
receiving a coolant through an inlet pipe;
propagating the coolant into a coolant distribution chamber that is coupled to the inlet pipe;
propagating the coolant through a plurality of distribution pipes that are coupled to the coolant distribution chamber, a respective distribution pipe comprising:
a first plurality of calibrated holes along a length of the respective distribution pipe,
an open end structured to receive coolant from the coolant distribution chamber, and
a closed end that is opposite to the open end and structured to prevent the coolant from flowing through the closed end;
propagating the coolant into a plurality of device chambers, a respective device chamber comprising:
a cavity, wherein the cavity is configured to contain a device that generates heat,
a first side comprising a second plurality of calibrated holes structured to allow the coolant to flow from the first plurality of calibrated holes to the cavity, and
a second side comprising a third plurality of calibrated holes structured to allow the coolant to flow out of the respective device chamber;
propagating the coolant into a coolant separation chamber that is coupled to at least one device chamber of the plurality of device chambers, the coolant separation chamber comprising a separator layer bisecting the coolant separation chamber into a first portion of the coolant separation chamber and a second portion of the coolant separation chamber;
propagating the coolant from the first portion of the coolant separation chamber into the second portion of the coolant separation chamber through a fourth plurality of calibrated holes in the separator layer; and
expelling, using an external pump that is operatively engaged with the holding unit, the coolant through an outlet pipe, wherein the outlet pipe is connected to the coolant separation chamber.

12. The cooling method of claim 11, wherein the coolant comprises at least one of is a liquid with a dielectric property of at least 0.10 watts (W).

13. The cooling method of claim 11, wherein the device is a circuit board.

14. The cooling method of claim 11, wherein the coolant separation chamber is coupled to the at least one device chamber such that the coolant flows from the at least one device chamber through respective third pluralities of calibrated holes into the coolant separation chamber.

15. The cooling method of claim 14, wherein the respective third pluralities of calibrated holes are sized based on at least one of the total coolant within the holding unit and a length of the holding unit.

16. A cooling system comprising:
an inlet pipe;
a holding unit comprising:
a first plurality of walls each comprising a respective top and respective bottom, a wall of the first plurality of walls joined with the inlet pipe;
a roof joined to the tops of the first plurality of walls;
a first floor joined to the bottoms of the first plurality of walls;
a coolant distribution chamber coupled with the inlet pipe;
a plurality of distribution pipes, coupled with the coolant distribution chamber, a respective distribution pipe comprising:
a first plurality of calibrated holes along a length of the respective distribution pipe,
an open end structured to receive coolant from the coolant distribution chamber, and
a closed end that is opposite to the open end and structured to prevent the coolant from flowing through the closed end;
a plurality of device chambers, a respective device chamber comprising:
a cavity surrounded by the second plurality of walls, the cavity being structured to contain a device that generates heat,
a second plurality of walls each comprising a respective top and respective bottom, the tops of the second plurality of walls joined with the roof,
a second floor joined to the bottoms of the second plurality of walls, the second floor comprising a second plurality of calibrated holes structured to allow the coolant to flow from the first plurality of calibrated holes to the cavity, and
a wall of the second plurality of walls comprising a third plurality of calibrated holes structured to allow coolant to flow out of the respective device chamber; and
a coolant separation chamber coupled to at least one device chamber of the plurality of device chambers, the coolant separation chamber comprising:
a separator layer bisecting the coolant separation chamber into a first portion of the coolant separation chamber and a second portion of the coolant separation chamber, and
a fourth plurality of calibrated holes in the separator layer, the fourth plurality of calibrated holes structured to allow coolant to flow from the first portion of the coolant separation chamber into the second portion of the coolant separation chamber;
an outlet pipe coupled with the coolant separation chamber; and
an external pump coupled with the outlet to expel the coolant from the coolant separation chamber through the outlet pipe.

17. The cooling system of claim 1, wherein the roof comprises a plurality of lids, the plurality of lids removably coupled to the tops of the first plurality of walls.

18. The cooling system of claim 17, wherein a lid of the plurality of removable lids comprises a cable passage.

19. The cooling system of claim 16, wherein the outlet pipe is coupled with the second portion of the coolant separation chamber.

20. The cooling system of claim 16, wherein the coolant separation chamber is coupled to the at least one device chamber such that the coolant flows from the at least one device chamber through respective third pluralities of calibrated holes into the coolant separation chamber.
